(19) United States
(12) Patent Application Publication
(10) Pub. No.: US 2025/0004031 A1
(43) Pub. Date: Jan. 2, 2025

(54) CABLE FAULT DETECTION BASED ON FMCW RADAR

(71) Applicant: Alex and Alice, Inc., Boyds, MD (US)

(72) Inventor: Zhonghai WANG, Boyds, MD (US)

(21) Appl. No.: 18/342,263

(22) Filed: Jun. 27, 2023

(51) Int. Cl. G01R 31/11; G01R 31/08; G01S 7/35; G01S 13/88

(52) U.S. Cl. CPC G01R 31/11; G01R 31/088; G01S 7/352; G01S 13/88

(57) ABSTRACT

A cable fault detection system includes a frequency-modulated continuous-wave (FMCW) signal generator, an amplifier connected with the FMCW signal generator, an impedance matcher, a lead cable connected with the impedance matcher, a mixer, a first signal distributor, a second signal distributor, a cable dictionary, and a data processer. The first and second signal distributors are connected with the amplifier, the impedance matcher, and the mixer. The data processer is connected with the mixer for performing cable fault detection using the cable dictionary and a signal from the mixer.

### GOVERNMENT RIGHTS

This invention was made with Government support under Contract No. W31P4Q-22-C-0048, awarded by the United States Army. The U.S. Government has certain rights in the present disclosure.

### TECHNICAL FIELD

The present disclosure generally relates to the field of cable fault diagnosis technology and, more particularly, relates to cable fault detection, localization, and cable state estimation based on a frequency-modulated continuous-wave (FMCW) radar.

### BACKGROUND

The integrity of cables is critical to the operation of an electrical system. To detect the cable fault, measurements can be performed at one end of the cable using reflectometry technologies. Cables are usually interrogated in time domain, frequency domain, or joint time-frequency domain. For example, an incident signal is sent to one port of a cable, a reflected signal from a faulty area is received at the same port, and then the reflected signal is analyzed to detect and locate a cable fault. In addition, the reflected signal is also analyzed to estimate the cable status, such as whether the cable is still usable or should be repaired or replaced immediately.

### BRIEF SUMMARY OF THE DISCLOSURE

An aspect of the present disclosure provides a cable fault detection and localization sensor system based on FMCW radar. The sensor system may also be referred to as a cable fault detector or sensor. The sensor may have a long working range, high fault detection sensitivity, and high fault localization accuracy (e.g., 1 inch or better). It may detect both soft and hard cable faults.

The sensor includes an FMCW radar, a data processor, and a user interface (UI). In some embodiments, the sensor may further include an impedance matcher and a lead cable.

The FMCW radar may include an FMCW signal generator, a transmitter low pass filter (LPF), a transmitter amplifier, a first signal distributor (e.g., a power splitter or a directional coupler), a second signal distributor (e.g., a circulator, a directional coupler, or a power splitter), a receiver mixer, a baseband receiver, and an analog to digital converter (ADC). The FMCW signal generator, transmitter LPF, transmitter amplifier, first signal distributor, and second signal distributor form a transmitter chain. The transmitter chain is configured to generate desired radar waveforms, provide a local oscillator for a radar receiver chain, and transmit measurement signals. The radar receiver chain includes the second signal distributor, receiver mixer, baseband receiver, and ADC. The radar receiver chain is arranged to receive a reflected signal, convert the reflected signal to a baseband signal, filter the baseband signal, amplify the baseband signal to a proper level, and then sample the baseband signal for digital processing at the data processor. Optionally, the radar receiver chain may further include a low noise amplifier (LNA) to amplify the reflected signal to improve the radar detection sensitivity, and a receiver LPF to compress the high frequency components of the received signal.

The data processor may include a microcontroller, a digital signal processor, a smart device (e.g., a smartphone), or a personal computer (e.g., a laptop computer or a desktop computer). The data processor accepts parameters selected or input by a user, configures radar waveform parameters and measurement processes, receives and processes baseband signal samples to detect and locate a cable fault, estimates a cable state, and sends fault detection and localization results to the user interface.

The user interface enables a user to select the radar waveform parameters, select target cable characteristics (or input target cable parameters), select a fault detection or measurement method, and display fault detection results and cable state estimation results.

In some embodiments, the sensor may include an impedance matcher to reduce the signal reflection by the lead cable (or the target cable when a lead cable is not used). It may improve the radar transmitter power efficiency.

In some embodiments, the sensor may include a lead cable that has the same impedance as or very close impedance with that of the target cable. The lead cable may push the transmitter leakage away from the desired target signal for a higher receiver signal to noise ratio (SNR). The lead cable impedance may match the target cable impedance to reduce signal reflection at the interface between the lead and target cables.

In some embodiments, the sensor may include a cable dictionary, which provides parameters of the target cable, such as the cable velocity factor, unit length insertion loss, maximum acceptable extra insertion loss, etc. The cable dictionary enables fast and convenient cable fault detection utilizing data obtained from the FMCW radar. For example, the data processor may estimate the target cable state using information retrieved from the cable dictionary, and determine if the target cable is defective and should be repaired or replaced.

In some embodiments, the sensor may apply multiple waveforms with different parameters to obtain desired measurements that have, e.g., different working ranges, high fault localization accuracy, and/or certain specific objectives (e.g., non-paired wire break detection and localization) for various target cables.

Another aspect of the present disclosure provides a multi-measurement method to obtain high fault localization accuracy using a set of radar waveforms with limited bandwidths. In some embodiments, FMCW waveforms with different bandwidths and different range resolutions are applied in multiple measurements. As the measurements have randomized fault localization errors, when the measurements are averaged to estimate the fault location, higher fault localization accuracy may be obtained.

Another aspect of the present disclosure provides an algorithm to detect and locate a break of a non-paired wire. In the algorithm, the non-paired wire is considered as a ¼ wave antenna radiation element. An FMCW radar generates a set of narrowband chirps. A long lead cable (e.g., its length matching the chirp bandwidth) is provided. The reflected signal power at the interface of the lead cable and target cable is measured over a frequency range. In the ¼ wave antenna working bandwidth, most of the input signal power is radiated. Out of the antenna working bandwidth, most of the input signal power is reflected. By measuring the reflected signal power over a frequency range, the working frequency center of the 1 wave antenna may be detected, and the break of the non-paired wire may be sensed and located.

In one aspect of the present disclosure, a cable fault detection system includes an FMCW signal generator for generating an FMCW signal, a first amplifier connected with the FMCW signal generator for amplifying the FMCW signal, a first signal distributor, a second signal distributor, an impedance matcher, a lead cable connected with the impedance matcher, a mixer, a cable dictionary, and a data processer. The impedance matcher directs an amplified FMCW signal to the lead cable. The lead cable is arranged for transmitting the amplified FMCW signal, receiving a reflected signal corresponding to the amplified FMCW signal, and directing the reflected signal to the impedance matcher. The first signal distributor routes the amplified FMCW signal to the receiver mixer as the local oscillator and to the second signal distributor. The second signal distributor routes the FMCW signal to the impedance matcher to transmit and routes the reflected signal from the impedance matcher to the mixer. The data processer collects digitalized baseband signal from the baseband receiver for performing cable fault detection using the cable dictionary.

In another aspect of the present disclosure, a method for cable fault detection includes generating an FMCW signal at an FMCW signal generator, directing the FMCW signal to a mixer as a local oscillator through a first signal distributor, directing the FMCW signal to an impedance matcher through a first and a second signal distributor, directing the FMCW signal from the impedance matcher to a lead cable, emitting the FMCW signal at an end of the lead cable, directing a reflected signal from the lead cable to the impedance matcher, directing the reflected signal from the impedance matcher to a mixer via the second signal distributor, amplifying the baseband signal (or the mixer output), digitizing the baseband signal and directing the digitized baseband to a data processor, and performing cable fault detection using the received signal and information retrieved from a cable dictionary.

In another aspect of the present disclosure, a cable fault detection system includes an FMCW signal generator for generating an FMCW signal, an impedance matcher, a lead cable, a mixer, a first signal distributor, a second signal distributor, and a data processer. The lead cable is connected with the impedance matcher and arranged for transmitting the FMCW signal, receiving a reflected signal corresponding to the FMCW signal, and directing the reflected signal to the impedance matcher. The first signal distributor is connected with the FMCW signal generator, the mixer, and the second signal distributor, directs the FMCW signal to the mixer as the local oscillator and to the second signal distributor as the transmitting signal. The second signal distributor is connected with the first signal distributor, the impedance matcher, and the mixer, directs the FMCW signal to the impedance matcher, and directs the reflected signal from the impedance matcher to the mixer. The data processer is connected with the mixer for performing cable fault detection using a received signal from the mixer.

Other aspects or embodiments of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments and are not intended to limit the scope of the present disclosure.

FIG. 1 is a block diagram illustrating an exemplary cable fault detector based on FMCW radar in accordance with various embodiments of the present disclosure; and

FIG. 2 illustrates an exemplary method for cable fault detection in accordance with various embodiments of the present disclosure.

### DETAILED DESCRIPTION

Reference will now be made in detail to exemplary embodiments of the disclosure, which are illustrated in the accompanying drawings.

As used herein, terms “connected” and “coupled” have the same meaning in the present disclosure. The term “connected” or “coupled” not only indicates two devices (or components) are connected or coupled without an intermediate device (or component) therebetween but also indicates two devices (or components) are connected or coupled with one or more intermediate devices (or components) therebetween.

The reflected signal's amplitude (V_{ref}) depends on the reflection coefficient (Γ) and the incident signal's amplitude (Vᵢ), and V_{ref}=Γ·Vᵢ. With the cable characteristic impedance (Z₀) and the cable impedance (Z₁) due to the fault, Γ=(Z₁−Z₀)/(Z₁+Z₀). The power return loss (RL) is defined as RL=−20 log₁₀|Γ|=−10 log₁₀(P_{ref}/Pᵢ), where P_{ref} is the reflected signal power and Pᵢ is the incident signal power. A larger cable impedance mismatch leads to a higher reflected signal power.

Time domain reflectometry (TDR) algorithms and time-frequency domain reflectometry (TFDR) algorithms transmit a short pulse (e.g., down to several nanosecond pulse width) at a carrier frequency. Both TDR and TFDR algorithms require high sampling rate at the receiver (Rx). The system performance is limited by the transmitted signal energy (e.g., short pulse duration and limited power) and the sensor sampling rate. For a low size, weight, and power (SWaP) sensor, the obtainable working range is limited, and the fault localization accuracy depends on the transmitted signal pulse width and the sampling rate. Traditional frequency domain reflectometry (FDR) algorithms depend on the phase change analysis on multiple signals with different frequencies. While the accuracy can be high using a large number of signals with different frequencies, the measurement time is long for transmitting and receiving these signals.

For radio frequency (RF) signals, a coaxial cable or a paired cable has characteristic impedance. When there is a fault, such as a shield with a broken part at a coaxial cable or a deformation at a twisted pair cable, the cable's characteristic impedance changes. This change generates an impedance discontinuity, which reflects back part of or all the incoming signal power. By measuring and analyzing reflected signals from the cable fault, the cable fault can be detected and located, and the fault property can be used for cable state estimation.

The cable fault reflection coefficient is determined by the fault property. A soft fault means a small impedance change, which reflects a small part of the incoming signal power. For example, an SMA connecter connecting two coaxial cables may cause an impedance mismatch between the two coaxial cable sections and reflection of a small part of the incoming signal power. A hard fault, such as an open circuit or a short circuit, may reflect almost all of the incoming signal power.

A frequency-modulated continuous-wave (FMCW) radar transmits an FMCW (or a chirp) signal to a target in a three-dimensional (3D) environment, receives an echo signal reflected by the target, converts the received signal to baseband signals, and then processes the baseband signals to detect and locate the target. The transmitted chirp signal may be a linear chirp described with

S_{T}(t)=a_{T}·cos[2π(f₀+Kt)t+θ₀],

where a_{T} is the transmitted signal amplitude, f₀ is the start frequency of the chirp, K is the signal's chirp rate, 0≤t≤T, T is the chirp duration, and θ₀ is the signal's initial phase. Its frequency is f_{T}(t)=f₀+Kt. The radar received signal is

S_{R}(t)=a_{R}·cos[2π(f₀+K(t−Δt))t+θ₀],

where a_{R} is the received signal amplitude, Δt=2r/(VF·C) is the two-way signal propagation time delay, r is the distance from the radar to the target, VF is the media velocity factor, and C is the RF signal traveling speed in the air. The received signal frequency is f_{R}(t)=f₀+K(t+Δt). The baseband signal is

S_{B}(t)=a_{M}·S_{R}(t)·S_{T}(t)=a_{B}·cos[2π(KΔt)t],

where a_{M} is the gain/attenuation of the receiver, and a_{B}=½·a_{M}·a_{T}·a_{R} is the baseband signal amplitude. The baseband signal frequency is f_{B}=KΔt. In the FMCW radar signal processing, f_{B} can be detected and the target distance r can be calculated.

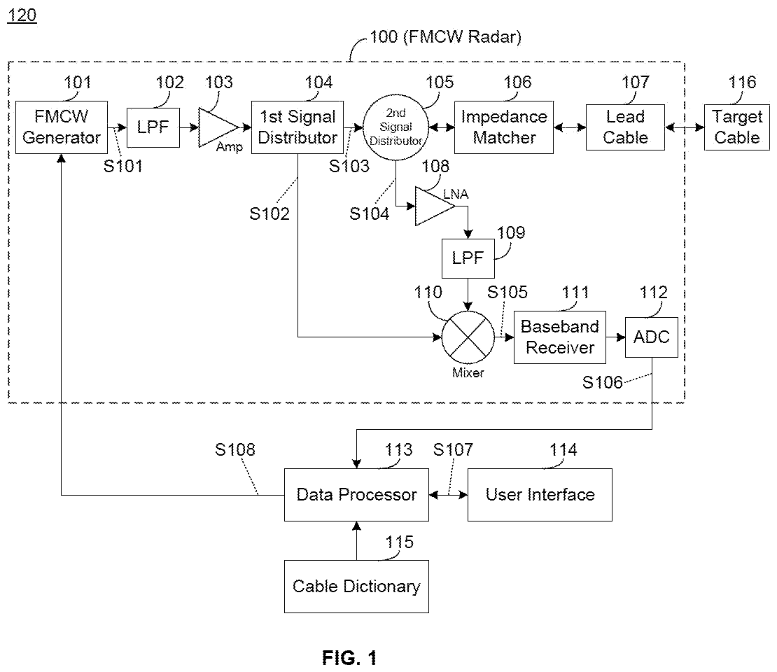

FIG. 1 shows a block diagram of an exemplary cable fault detector 120 according to the present disclosure. The cable fault detector 120 may also be considered as a cable fault detection system. The cable fault detector 120 includes an FMCW radar 100, a data processor 113, and a user interface 114. Optionally, the cable fault detector 120 may also include a cable dictionary 115. The FMCW radar 100 may be viewed as an FMCW radar with a single antenna. But unlike a conventional FMCW radar, the FMCW radar 100 does not have a conventional antenna to emit signals. Instead, it emits FMCW signals at an end of a cable, such as a port (not shown) of a lead cable 107. The lead cable 107 is configured to connect with a target cable 116 under test. That is, the port of the lead cable 107 connects with and directs FMCW signals to a port (not shown) of the target cable 116.

As shown in FIG. 1, the FMCW radar 100 includes an FMCW signal generator 101, a transmitter LPF 102, a transmitter amplifier 103, a first signal distributor 104, a second signal distributor 105, a receiver mixer 110, a baseband receiver 111, and an ADC 112. In some embodiments, the FMCW radar 100 may include an impedance matcher 106 and the lead cable 107. The first signal distributor 104 may be a power splitter or a directional coupler. The second signal distributor 105 may be a circulator, a power splitter, or a directional coupler. Optionally, the FMCW radar 100 may further include a receiver LNA 108 and a receiver LPF 109.

Components such as the FMCW signal generator 101, transmitter LPF 102, transmitter amplifier 103, first signal distributor 104, second signal distributor 105, impedance matcher 106, and lead cable 107 form a transmission path. The transmission path is configured for transmitting FMCW signals from the FMCW signal generator 101 to the target cable 116. Some components in the transmission path are connected with each other in series directly, such as the transmitter LPF 102 and FMCW signal generator 101. Some components in the transmission path are connected with each other in series indirectly, such as the impedance matcher 106 and FMCW signal generator 101. Optionally, there may be fewer or more components (e.g., a filter, an amplifier, a splitter, or coupler) at the transmission path.

The FMCW signal generator 101 may include a direct digital synthesizer (DDS) (e.g., the Analog Devices AD9914, AD9915, or AD9174 synthesizer), a reference FMCW signal generator plus a Phase Lock Loop (PLL) and a voltage-controlled oscillator (VCO), or a sawtooth generator plus a VCO. The FMCW signal generator 101 generates the desired FMCW signals S101 for measurements according to instructions arranged by a user. The start frequency and stop frequency of the FMCW signal S101 is determined by the target cable cutoff frequency, the desired fault localization accuracy, and the FMCW signal generator's capability. When a DDS is used to generate FMCW signals, certain FMCW signal parameters may be configured in a wide range. The FMCW signal frequency may be as low as several hertz or as high as several gigahertz. The FMCW signal chirp rate may be configured according to the needs of applications. For example, the FMCW signal chirp rate may be relatively low in cable length measurements, and relatively high in cable fault detections.

The transmitter LPF 102 filters out undesired high frequency components generated by the FMCW signal generator 101. The transmitter amplifier 103 amplifies filtered FMCW signals to a higher power level. Optionally, the amplified signals may be referred to as measurement signals. The first signal distributor 104 divides the measurement signals into two parts, signals S102 and S103. Signals S102 are directed to the receiver mixer 110 and serve as a receiver mixer's local oscillator, while signals S103 are transmitted toward the second signal distributor 105.

The second signal distributor 105 has three functions. First, it directs signals S103 to the impedance matcher 106. Second, it gets reflected signals from impedance matcher 106 and directs the reflected signals to the receiver mixer 110. Third, it compresses the transmitter (Tx) leakage at the receiver channel.

Compared to a conventional FMCW radar, the FMCW radar 100 directs transmitter signals to a target cable and obtains reflected signals from the target cable, instead of radiating transmitter signals into a 3D sensing space via an antenna and receiving a tiny fraction of the reflected signals from a target via the antenna. As such, the reflected signals obtained by the FMCW radar 100 may be much stronger that that received by a conventional FMCW radar. Thus, the FMCW radar 100 may tolerate certain internal power loss and higher insertion loss parts may be applied. The second signal distributor 105 may be built with a circulator, a directional coupler, or a power splitter in some embodiments. Directional couplers are low cost and suitable for wideband signals, while circulators are expensive and suitable for relatively narrow band signals. With a directional coupler or circulator, the Tx leakage compression may be relatively high (e.g., about 20 dB). With a power splitter, the Tx leakage compression may be relatively low (e.g., about 10 dB).

As aforementioned, the FMCW radar 100 may further include a receiver LNA 108 and a receiver LPF 109. The optional receiver LNA 108 amplifies received signals S104 to reduce the radar receiver noise figure. The receiver LPF 109 filters the received signals to compress the high frequency noise.

The receiver mixer 110 converts the received signals to baseband signals S105. The baseband signals S105 are filtered to remove high frequency components and amplified to a proper level before being directed to the ADC 112. The ADC 112 converts baseband signals S105 to digital samples S106 (i.e., digitalized baseband signals S106) for signal processing at the data processor 113.

Components such as the second signal distributor 105, impedance matcher 106, lead cable 107, receiver LNA 108, receiver LPF 109, receiver mixer 110, baseband receiver 111, and ADC 112 form a receiving path. The receiving path is arranged to receive and process the reflected signals that are received at the lead cable 107 and directed to the data processor 113. Like the transmission path, components at the receiving path are connected with each other in series directly or indirectly. Optionally, there may be fewer or more components (e.g., a filter, an amplifier, a splitter, or coupler) at the receiving path.

The impedance matcher 106 allows impedance matching between the signal distributor 2 and the lead cable. It may enhance the radar power efficiency by reducing the signal power reflection by the target cable 116 due to the impedance mismatching. The lead cable 107 transmits signals to the target cable and the impedance matcher, respectively, and pushes the interested target signal far away from the transmitter leakage for obtaining high SNR measurements. The lead cable 107 may be long enough (e.g., longer than a preset value) such that the target cable 116 is in a range where the transmitter leakage is much lower than the power of the reflected signal generated by a cable fault. The lead cable characteristic impedance may match that of the target cable for reducing the power reflection at the interface. In non-paired wire break point detection and localization, the length of the lead cable may match the measurement signal bandwidth.

Alternatively, the FMCW radar 100 may not have the impedance matcher 106 and/or the lead cable 107 in some cases. That is, the FMCW radar 100 may be connected with the target cable 116 without at least one of the impedance matcher 106 and lead cable 107. For example, a port of the second signal distributor 105 may be connected to a port of the target cable 116 directly in some aspects.

After a user enters instructions at the user interface 114, the data processor 113 receives the user input through communication signals S107. The data processor 113 configures radar parameters and controls the radar working mode via communication signals S108 according to the user input. The data processor 113 collects and processes digitalized baseband signals S106 for cable fault detection, fault localization, and cable state estimation.

With reference to FIG. 1, the FMCW signal S101 may be a linear chirp with a frequency of

f_{T}(t)=f₀+Kt, 0≤t≤T,

where f₀ is the chirp starting frequency, K is the chirp rate, and T is the chirp signal time duration. The frequency of the cable fault reflection signal S104 may be

f_{R}(t)=f₀+K(t−Δt),

where Δt=(2r)/(VF·C) is the two-way time delay generated by the distance r between the radar and the cable fault location, VF is the velocity factor of the target cable, and C is the RF signal traveling speed in the air. The baseband signal frequency is

f_{B}=f_{T}−f_{R}=K·Δt.

The frequency of the baseband signal S105 may be estimated by calculating the spectrum of the digitized baseband signal S106. Further, the reflected signal's time delay Δt and the target distance r may be calculated with the known waveform chirp rate K and the target cable velocity factor VF.

The user interface 114 enables a user to interactively operate the cable fault detector 120. The user may select the target cable's cable group from the cable dictionary. If the target cable is not included in the cable dictionary, the user may input cable parameters such as the velocity factor and unit length insertion loss at the user interface 114. The user may select the sensor working mode from a prearranged set or a prearranged list, select a single waveform for normal cable fault detection and localization, or select multiple waveforms for high accuracy cable fault localization. The user may also scan a frequency range for break point detection and localization of non-paired wires.

It may be impractical to use conventional FMCW radars for cable fault detections, as these radars have one or more antennas for 3D sensing, instead of a connection component configured for coupling with a target table. In particular, these radars do not have the impedance matcher and lead cable for low-loss and low-noise connection with a target cable, do not have a cable dictionary for fast and convenient cable fault detections, and their working frequency may be higher than some cables' cutoff frequency. The impedance matcher 106, lead cable 107, cable dictionary 115, and a large bandwidth FMCW signal at low frequency (e.g., several megahertz to several gigahertz) are designed to make an FMCW radar suitable for cable fault diagnosis. The cable dictionary 115 may include information (or data) of various types of cables and other information arranged for cable fault detections. In some cases, the cable dictionary 115 may contain a lookup table that stores the information.

In some embodiments, the FMCW radar 100 may generate different waveforms with different parameters (e.g., start/stop frequency, bandwidth, chirp rate, chirp duration, etc.) for working with different cables having different cutoff frequencies, and for obtaining a long working range with a lower chirp rate or a high fault localization accuracy with a higher chirp rate.

In some embodiments, a multi-measurement method may be configured to obtain high fault localization accuracy using a set of waveforms. Each waveform has a different bandwidth and therefore a different range resolution. Fault range measurements are conducted using the set of waveforms, respectively. The fault range measurements have randomized fault localization errors. The final cable fault location is calculated by averaging results (e.g., averaging multiple range values) obtained from the fault range measurements. As such, high fault localization accuracy may be obtained. An exemplary set of waveforms is presented in Table 1. When the set of waveforms is used, the accuracy of cable fault location may be better than 1 inch (or 25.4 millimeters) in some cases. When higher fault localization accuracy is needed, a larger waveform set with more waveforms may be arranged in some other cases. The larger waveform set may have smaller range resolution difference between neighboring waveforms.

TABLE 1
An exemplary set of waveforms

| | | Chirp | | Range | Start | Stop |
|---|---|---|---|---|---|---|
| Waveform | Chirp rate | duration | BW | resolution | Freq. | Freq. |
| number | (GHz/s) | (ms) | (MHz) | (m) | (MHz) | (MHz) |
| 1 | 950 | 1.000 | 950.000 | 0.104 | 40 | 990.00 |
| 2 | 950 | 0.947 | 900.000 | 0.110 | 40 | 940.00 |
| 3 | 950 | 0.868 | 825.000 | 0.120 | 40 | 865.00 |
| 4 | 950 | 0.802 | 761.538 | 0.130 | 40 | 801.54 |
| 5 | 950 | 0.744 | 707.143 | 0.140 | 40 | 747.14 |
| 6 | 950 | 0.695 | 660.000 | 0.150 | 40 | 700.00 |
| 7 | 950 | 0.651 | 618.750 | 0.160 | 40 | 658.75 |
| 8 | 950 | 0.613 | 582.350 | 0.170 | 40 | 622.35 |
| 9 | 950 | 0.579 | 550.000 | 0.180 | 40 | 590.00 |
| 10 | 950 | 0.548 | 521.050 | 0.190 | 40 | 561.05 |

In some embodiments, an algorithm may be provided to detect and locate a single non-paired wire break. In the algorithm, the non-paired wire is considered as a radiation element of a ¼ wave antenna of the FMCW radar 100. The antenna resonant frequency (f) is calculated with f=VF*C/(4d), where VF is the cable velocity factor, C is the RF signal propagation speed in the air, and d is the length of the antenna radiation element. The lead cable 107 may have a length l that matches the chirp bandwidth (e.g., l=VF_{lead}*C/(2BW_{chirp}), where VF_{lead} is the lead cable velocity factor, and BW_{chirp} is the chirp bandwidth. A narrow bandwidth chirp may be generated at the FMCW signal generator 101 to measure the reflected signal power at the interface of the lead cable 107 and the non-paired wire over a frequency range. When the input signal frequency is in the ¼ wave antenna working bandwidth, most of the input signal power is radiated and only a small amount of the signal power is reflected. When the input signal frequency is not in the ¼ wave antenna working bandwidth, most of the input signal power is reflected. The resonant frequency of the ¼ wave antenna is

fₐₙₜₑₙₙₐ=arg min_{f} P_{R}(f),

where P_{R} (f) is the power of the reflected signal with the chirp centered at f. When the resonant frequency is detected, the length of the target cable may be calculated with d=VF*C/(4fₐₙₜₑₙₙₐ). When d is shorter than the original cable length, a break in the no-paired wire is detected and located. An exemplary waveform set to measure the length of a single wire (e.g., with a length of 1 to 2 meters) may be arranged as follows: BW_{chirp}=4 MHz, K=6 GHz/s, T=0.667 ms, and center frequencies starting from 32 MHz with 1 MHz step and ending at 72 MHz. There may be totally 41 waveforms to measure the reflected signal power to estimate the single wire length. When a finer range resolution is needed, the waveform center frequency step may be configured smaller.

Compared with conventional sensor systems using time domain and joint time-frequency domain cable fault diagnosis algorithms, the above-described sensor system (e.g., the cable fault detector 120) may have a much lower sampling rate and a longer working range. Compared with conventional sensor systems using frequency domain cable fault diagnosis algorithms, the above-described sensor system (e.g., the cable fault detector 120) may have much higher fault localization accuracy and a higher measurement speed. The above-described sensor system and sensing methods may be applied for cable fault detection and localization and cable length measurement for various types of cables, such as coaxial cables, twisted paired cables, parallel paired cables, single non-paired wires, etc.

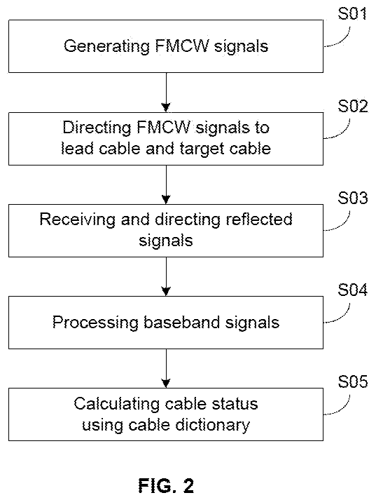

FIG. 2 shows a schematic flow chart to illustrate methods for cable fault detection according to the present disclosure. The method is based on a single-antenna FMCW radar (e.g., the FMCW radar 100 as shown in FIG. 1). At S01, FMCW signals are generated at an FMCW signal generator (e.g., the FMCW signal generator 101 as shown in FIG. 1). The FMCW signal generator may contain a DDS or a sawtooth generator plus a VCO. The start and stop frequencies of the FMCW signals may be determined by the user.

At 502, the FMCW signals are directed to a LPF, an amplifier, and then a first signal distributor. The FMCW signals are filtered by the LPF and amplified by the amplifier. The first signal distributor directs a first part of the FMCW signals to a mixer (e.g., the receiver mixer 110 as shown in FIG. 1) and directs a second part of the FMCW signals to a second signal distributor (e.g., the second signal distributor 105 as shown in FIG. 1). The second signal distributor directs the FMCW signal from the first signal distributor to an impedance matcher (e.g., the impedance matcher 106 as shown in FIG. 1). The impedance matcher then directs the coming FMCW signal to a lead cable (e.g., the lead cable 107 as shown in FIG. 1). Thereafter, the FMCW signal is directed to (or coupled with) a target cable for cable fault detection. The impedance matcher may improve the radar power efficiency. The lead cable may improve the SNR of measurements.

At S03, reflected signals are received at the end of the lead cable. The reflected signals are transmitted to the impedance matcher via the lead cable, and then directed to the mixer by the second signal distributor. The mixer converts the reflected signals into baseband signals. In some embodiments, the reflected signals are amplified by a receiver LNA and filtered by a receiver LPF before reaching the mixer. In some other embodiments, the baseband signals may be amplified by a receiver amplifier and filtered by a receiver LPF after exiting the mixer.

At S04, the baseband signals (e.g., the baseband signals S105 as shown in FIG. 1) are directed from the mixer to a baseband receiver. The baseband signals from the mixer are processed by the baseband receiver. For example, the baseband signals may be filtered and then amplified by the baseband receiver. The baseband signals are then converted to digital samples or digitalized baseband signals (e.g., the digitalized baseband signal S106 as shown in FIG. 1) by an ADC. Thereafter, the digitalized baseband signals are directed to a data processor from the ADC.

At S05, the digitalized baseband signals sent from the ADC are collected and processed by the data processor for cable fault detection. For example, a cable fault location may be calculated and a cable state may be estimated by the data processor. Information of the target cable may be retrieved from a cable dictionary connected to the data processor and used in the cable fault calculation and estimation. The cable dictionary may contain data of various types of cables arranged in cable groups. Information of cables includes parameters such as velocity factor, unit length insertion loss at various frequencies, and allowable extra insertion loss.

In some cases, different waveforms with different parameters (e.g., start/stop frequency, bandwidth, chirp rate, chirp duration, etc.) may be generated by the FMCW signal generator, respectively. As such, the FMCW radar 100 may work with different cables and obtain a long working range or a high fault localization accuracy.

In some embodiments, a detection process involves multiple measurements that are implemented, respectively. Different waveforms (e.g., different bandwidths) are generated by the FMCW signal generator in the measurements. Besides different range resolution values, the measurements with different waveforms have randomized localization errors. When location values of the measurements are averaged, a part of the errors is canceled and thus the average fault location value may have improved fault localization accuracy.

When the target cable is a non-paired wire that has a break point, the target cable may be considered as a ¼ wave antenna radiation element of the single-antenna FMCW radar in some cases. Narrow bandwidth chirps over a frequency range may be made by the FMCW signal generator. As illustrated above, the antenna resonant frequency may be detected by analyzing the power of the reflected signals over the frequency range. Then, the length of the target cable from the output port of the lead cable to the break point may be calculated using the antenna resonant frequency.

The embodiments disclosed herein are exemplary only. Other applications, advantages, alternations, modifications, or equivalents to the disclosed embodiments are obvious to those skilled in the art and are intended to be encompassed within the scope of the present disclosure.

What is claimed is:

1. A cable fault detection system, comprising:
a frequency-modulated continuous-wave (FMCW) signal generator for generating an FMCW signal;
a first amplifier connected with the FMCW signal generator for amplifying the FMCW signal;
an impedance matcher;
a lead cable connected with the impedance matcher, the impedance matcher directing an amplified FMCW signal to the lead cable, the lead cable arranged for transmitting the amplified FMCW signal, receiving a reflected signal corresponding to the amplified FMCW signal, and directing the reflected signal to the impedance matcher;
a mixer;
a first signal distributor and a second signal distributor, the first signal distributor connected with the first amplifier, the second signal distributor, and the mixer, and directing the amplified FMCW signal to the mixer and to the second signal distributor, and the second signal distributor connected with the first signal distributor, the impedance matcher, and the mixer, directing the amplified FMCW signal from the first signal distributor to the impedance matcher, and directing the reflected signal to the mixer from the impedance matcher;
a cable dictionary; and
a data processer connected with the mixer for performing cable fault detection using the cable dictionary and a received signal from the mixer.

2. The system according to claim 1, wherein the second signal distributor includes a circulator.

3. The system according to claim 1, wherein the second signal distributor includes a power splitter or a directional coupler.

4. The system according to claim 1, wherein the first signal distributor includes a power splitter or a directional coupler.

5. The system according to claim 1, wherein the cable dictionary includes cable information corresponding to a plurality of cables, respectively.

6. The system according to claim 1, further comprising:
a second amplifier connected with the second signal distributor and the mixer for amplifying the reflected signal.

7. The system according to claim 1, further comprising:
a baseband receiver and/or an analog to digital converter (ADC) connected with the mixer and the data processor.

8. A method for cable fault detection, comprising:
generating a frequency-modulated continuous-wave (FMCW) signal at an FMCW signal generator;
directing the FMCW signal to a mixer through a first signal distributor and to an impedance matcher through the first signal distributor and the second signal distributor;
directing the FMCW signal from the impedance matcher to a lead cable;
emitting the FMCW signal at one end of the lead cable;
directing a reflected signal from the lead cable to the impedance matcher;
directing the reflected signal from the impedance matcher to a mixer via the second signal distributor;
directing a baseband signal from the mixer to a baseband receiver;
directing the baseband signal from the baseband receiver to an analog to digital converter (ADC);
directing a digitized baseband signal from the ADC to a data processor; and
performing cable fault detection and localization using the digitized baseband signal and information retrieved from a cable dictionary.

9. The method according to claim 8, wherein the first signal distributor includes a power splitter or a directional coupler.

10. The method according to claim 8, wherein the second signal distributor includes a circulator.

11. The method according to claim 8, wherein the second signal distributor includes a power splitter or a directional coupler.

12. The method according to claim 8, wherein the cable dictionary includes cable data corresponding to a plurality of cables, respectively.

13. The method according to claim 8, further comprising:
performing a plurality of measurements with different waveforms; and
averaging results of the plurality of measurements to obtain a fault location value.

14. The method according to claim 8, further comprising:
using a target cable as an antenna's radiation element to detect a length value of the target cable.

15. A cable fault detection system, comprising:
a frequency-modulated continuous-wave (FMCW) signal generator for generating an FMCW signal;
an impedance matcher;
a lead cable connected with the impedance matcher and arranged for transmitting the FMCW signal, receiving a reflected signal corresponding to the FMCW signal, and directing the reflected signal to the impedance matcher;
a mixer converting the reflected signal to a baseband signal;
a first signal distributor;
a second signal distributor, the first signal distributor connected with the FMCW signal generator, the second signal distributor, and the mixer, and directing the FMCW signal to the mixer as a local oscillator and to the second signal distributor for transmitting, and the second signal distributor connected with the first signal distributor, the impedance matcher, and the mixer, directing the FMCW signal to the impedance matcher, and directing the reflected signal from the impedance matcher to the mixer; and
a data processer connected with the mixer for performing cable fault detection using a received signal from the mixer.

16. The system according to claim 15, further comprising:
a cable dictionary connected with the data processor and including cable information corresponding to a plurality of cables, respectively.

17. The system according to claim 15, further comprising:
a first amplifier connected with the FMCW signal generator and the first signal distributor for amplifying the FMCW signal.

18. The system according to claim 15, further comprising:
a second amplifier connected with the second signal distributor and the mixer for amplifying the reflected signal.

19. The system according to claim 15, further comprising:
a baseband receiver and/or an analog to digital converter (ADC) connected with the mixer and the data processor.
